(19) United States
(12) Patent Application Publication
(10) Pub. No.: US 2016/0329443 A1
(43) Pub. Date: Nov. 10, 2016

(54) SOLAR CELL WITH A LOW-RESISTIVITY TRANSPARENT CONDUCTIVE OXIDE LAYER

(71) Applicant: SolarCity Corporation, San Mateo, CA (US)

(72) Inventors: Wei Wang, San Jose, CA (US); Christopher Y. Liao, Fremont, CA (US); Jianming Fu, Palo Alto, CA (US); Zheng Xu, Pleasanton, CA (US)

(21) Appl. No.: 14/705,845

(22) Filed: May 6, 2015

(51) Int. Cl. H01L 31/0224; H01L 31/18; H01L 31/0352; H01L 31/0368; H01L 31/074; C23C 14/08; H01L 31/0376

(52) U.S. Cl. CPC H01L 31/022466; C23C 14/086; H01L 31/1884; H01L 31/03762; H01L 31/03682; H01L 31/074; H01L 31/03529

(57) ABSTRACT

One embodiment of the present invention provides a solar cell that includes a crystalline silicon base layer, a first quantum tunneling barrier layer deposited on a first side of the base layer, and a second quantum tunneling barrier layer deposited on a second side of the base layer. The solar cell further includes a doped amorphous silicon emitter layer positioned on the first side of the base layer. The first quantum tunneling barrier layer is between the emitter layer and the base layer. Also included is a doped amorphous silicon surface field layer positioned on the second side of the base layer. The second quantum tunneling barrier layer is between the surface field layer and the base layer. The solar cell further includes a transparent conductive oxide layer adjacent to the emitter layer or surface field layer. The transparent conductive oxide layer comprises hydrogen and indium oxide, indium-titanium-oxide, or indium-tungsten-oxide.

### RELATED APPLICATION

This application claims the benefit of U.S. Provisional Application No. 62/092,151, Attorney Docket Number P77-1PUS, entitled “SOLAR CELL WITH A LOW-RESISTIVITY TRANSPARENT CONDUCTIVE OXIDE LAYER,” by inventors Wei Wang, Christopher Y. Liao, Jianming Fu, and Zheng Xu, filed 15 Dec. 2014.

### BACKGROUND

1. Field

This disclosure is generally related to the fabrication of a solar cell. More specifically, this disclosure is related to the fabrication of a solar cell with a low-resistivity transparent conductive oxide layer.

2. Related Art

The negative environmental impact of fossil fuels and their rising cost have resulted in a dire need for cleaner, cheaper alternative energy sources. Among different forms of alternative energy sources, solar power has been favored for its cleanness and wide availability.

A solar cell converts light into electricity using the photovoltaic effect. There are several basic solar cell structures, including a single p-n junction, p-i-n/n-i-p, and multi-junction. A typical single p-n junction structure includes a p-type doped layer and an n-type doped layer. Solar cells with a single p-n junction can be homojunction solar cells or heterojunction solar cells. If both the p-doped and n-doped layers are made of similar materials (materials with equal band gaps), the solar cell is called a homojunction solar cell. In contrast, a heterojunction solar cell includes at least two layers of materials of different bandgaps. A p-i-n/n-i-p structure includes a p-type doped layer, an n-type doped layer, and an intrinsic (undoped) semiconductor layer (the i-layer) sandwiched between the p-layer and the n-layer. A multi-junction structure includes multiple single-junction structures of different bandgaps stacked on top of one another.

In a solar cell, light is absorbed near the p-n junction, which in turn generates carriers. The carriers diffuse into the p-n junction and are separated by the built-in electric field, thus producing an electrical current across the device and external circuitry. An important metric in determining a solar cell's quality is its energy-conversion efficiency, which is defined as the ratio between power converted (from absorbed light to electrical energy) and power collected when the solar cell is connected to an electrical circuit. High efficiency solar cells are essential in reducing cost to produce solar energies.

An important component of a solar cell is the conductive anti-reflective layer that is placed between the cell structure and electrodes. Such a conductive anti-reflective layer is often based on a transparent conductive oxide (TCO) material. The TCO layer serves two purposes: (1) to reduce reflection and allow light to reach the cell structure; and (2) to provide a good ohmic contact between the cell structure and the electrodes. The optical transmission of the TCO depends on the TCO material's bandgap and refractive index, among other factors. The quality of the ohmic contact is determined by the TCO's resistivity, which depends on the carrier density and mobility.

### SUMMARY

One embodiment of the present invention provides a solar cell. The solar cell includes a crystalline silicon base layer, a first quantum tunneling barrier layer deposited on a first side of the base layer, and a second quantum tunneling barrier layer deposited on a second side of the base layer. The solar cell further includes a doped amorphous silicon emitter layer positioned on the first side of the base layer, wherein the first quantum tunneling barrier layer is between the emitter layer and the base layer. Also included in the solar cell is a doped amorphous silicon surface field layer positioned on the second side of the base layer, wherein the second quantum tunneling barrier layer is between the surface field layer and the base layer. The solar cell further includes a transparent conductive oxide layer adjacent to the emitter layer or surface field layer, wherein the transparent conductive oxide layer comprises hydrogen and indium oxide, indium-titanium-oxide, or indium-tungsten-oxide.

In a variation on this embodiment, the transparent conductive oxide layer has a resistivity less than 500 μΩ·cm.

In a further embodiment, the transparent conductive oxide layer has a resistivity less than 400 μΩ·cm.

In a variation on this embodiment, the transparent conductive oxide layer has a carrier density less than 3×10²⁰/cm³.

In a variation on this embodiment, the transparent conductive oxide layer has a carrier mobility greater than 70 cm²/(V·s).

In a variation on this embodiment, the transparent conductive oxide layer further comprises tin.

In a variation on this embodiment, the solar cell further includes a thin metal layer deposited on the transparent conductive oxide layer.

In a further variation, the solar cell further includes a copper electrode layer electroplated on the thin metal layer.

One embodiment of the present invention provides a method for fabricating a solar cell. During operation, a wafer with a solar cell structure is placed in a vacuum chamber. Subsequently, a transparent conductive oxide layer is deposited on the wafer in a deposition environment that contains water vapor or hydrogen gas, using a physical vapor deposition technique, wherein the transparent conductive oxide layer comprises indium oxide, indium-titanium-oxide, or indium-tungsten-oxide. Then, the transparent conductive oxide layer is annealed subsequent to the deposition.

In a variation on this embodiment, the deposition environment is maintained at a temperature lower than 250° C.

In a further variation, the deposition environment is maintained at a temperature between 25° C. and 100° C.

In a variation on this embodiment, the water vapor in the deposition environment has a pressure between 1×10⁻⁷ and 1×10⁻⁴ Torr.

In a further variation, the water vapor pressure is approximately 3-10×10⁻⁶ Torr.

In a variation on this embodiment, the annealing is performed for 15 to 60 minutes.

In a variation on this embodiment, the annealing is performed at approximately 150-200° C.

In a variation on this embodiment, the annealing is performed in air, vacuum, or an environment that contains N₂ and H₂.

In a variation on this embodiment, the physical vapor deposition technique comprises a sputtering process, which involves bombarding a target material in presence of water vapor or hydrogen, the target material comprising indium oxide, indium-titanium-oxide, or indium-tungsten-oxide.

### BRIEF DESCRIPTION OF THE FIGURES

FIG. 1A presents a diagram illustrating an exemplary sputtering system in accordance with one embodiment of the present invention.

FIG. 1B presents a flowchart illustrating an exemplary process for fabricating solar cells with a low-resistivity transparent conductive oxide layer in accordance with one embodiment of the present invention.

FIG. 2 presents a diagram illustrating an exemplary double-sided tunneling heterojunction solar cell, in accordance with an embodiment of the present invention.

FIG. 3 presents a diagram illustrating an exemplary process of fabricating a solar cell with a low-resistivity TCO layer and electrodes, in accordance with an embodiment of the present invention.

FIG. 4A illustrates the surface of an exemplary bifacial solar cell with a single center busbar, in accordance with an embodiment of the present invention.

FIG. 4B illustrates a cross-sectional view of the bifacial solar cell with a single center busbar per surface, in accordance with an embodiment of the present invention.

FIG. 4C illustrates a cross-sectional view of bifacial solar cell, in accordance with an embodiment of the present invention.

FIG. 5A presents a diagram illustrating the serial connection between two adjacent cells with low-resistivity TCO layers using a single edge busbar per surface, in accordance with an embodiment of the present invention.

FIG. 5B presents a diagram illustrating the side-view of a string of adjacent edge-overlapped cells with low-resistivity TCO layers, in accordance with an embodiment of the present invention.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention provide a method for fabricating low-resistivity transparent conductive oxide (TCO) thin films at a relatively low temperature, which prevents damages to the underlying solar cell structure. During the TCO fabrication process, a solar cell wafer is placed in a sputtering chamber. The TCO material used is In₂O₃, or In₂O₃ doped with TiO₂ or tungsten oxide (WO₂). During the sputtering process, in addition to Ar and O₂, water (H₂O) vapor or hydrogen gas (H₂) is supplied to the sputtering chamber. Meanwhile, the sputtering temperature is maintained below 250° C., preferably between 25° C. and 200° C., and more preferably between 25° C. and 100° C. After the desirable thickness of the TCO film is achieved, the solar cell undergoes an annealing process. The annealing can be done in air, vacuum, or an environment that contains N₂ and H₂, at approximately 100° C.-200° C., preferably 150° C.-200° C., for approximately 10-60 minutes, preferably 15-60 minutes. This process can ensure a TCO layer that has a low resistivity, and prevents damages to the solar cell structure due to the lowered process temperature during the sputtering process.

### Sputtering Process for TCO Fabrication

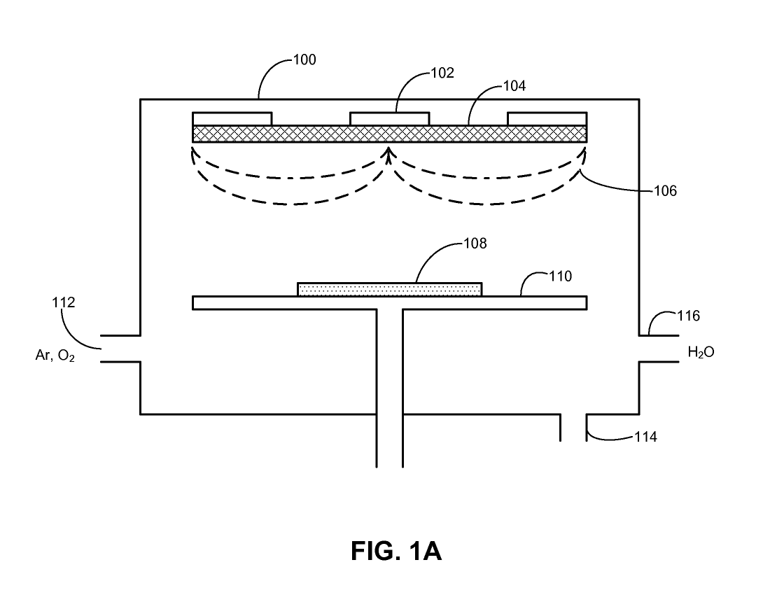

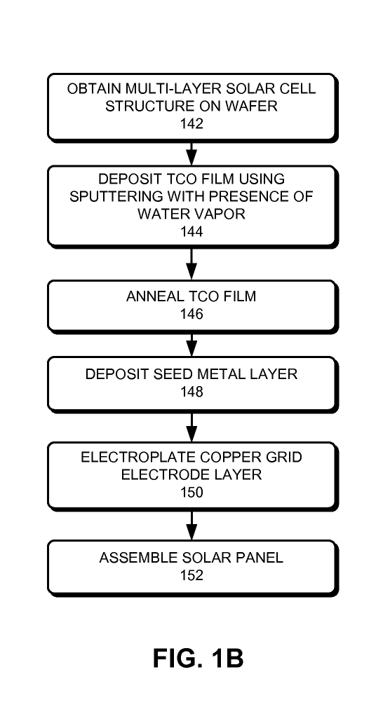

FIG. 1A presents a diagram illustrating an exemplary sputtering system, in accordance with one embodiment of the present invention. In this example, sputtering chamber 100 is maintained at a base vacuum pressure, which in one embodiment can be between 10⁻⁸-10⁻⁶ Torr. Within sputtering chamber 100 is cathode 102 which is electrically coupled to target 104. In one embodiment, target 104 can a mixture of In₂O₃ and TiO₂, a mixture of In₂O₃ and W, or In₂O₃ without any dopant. Within sputtering chamber 100 is also anode 110, which holds and supports wafer 108. Sputtering chamber 100 has one gas inlet 112, which supplies argon (Ar) and oxygen (O₂) gas for the sputtering process. Sputtering chamber 100 also has a second inlet 116, which supplies water vapor or hydrogen gas. Pump outlet 114 is used to pump sputtering chamber 100 down to the base pressure.

During the sputtering process, magnetic field 106 is created (for example by a magnetron) to confine free electrons in the vacuum. The working gases Ar and O₂ are supplied via inlet 112 and cause the chamber pressure to rise to a process pressure. In one embodiment, the chamber process pressure is maintained at 1-20 mTorr, preferably at 3-10 mTorr (due to the in-flow of Ar and O₂). When a doped In₂O₃ target is used (e.g., In₂O₃ doped with TiO₂ or WO₂), and if water vapor is introduced during sputtering, water vapor at a pressure of 10⁻⁷-10⁻³ Torr is supplied via inlet 116, with a flow rate of approximately 0.5-2 SCCM, preferably 1-1.5 SCCM. Meanwhile, Ar can be supplied at 80-150 SCCM, preferably at 120 SCCM, and O₂ can be supplied at 0-4 SCCM, preferably at 0-2 SCCM. If H₂ instead of water vapor is introduced during sputtering, the H2 is supplied via inlet 116 with a flow rate of approximately 1-5 SCCM, preferably 2-3 SCCM, while O₂ can be supplied at 2-10 SCCM, preferably at 4.5-7.5 SCCM, with Ar supplied at 80-150 SCCM, preferably at 120 SCCM. The chamber temperature is maintained below 250° C., preferably between 25° C. and 100° C.

When an undoped In₂O₃ target is used, and if water vapor is introduced during sputtering, water vapor at a pressure of 10⁻⁷-10⁻³ Torr is supplied via inlet 116, with a flow rate of approximately 0.5-3 SCCM, preferably 1.5-2.5 SCCM. Meanwhile, Ar can be supplied at 80-150 SCCM, preferably at 120 SCCM, and O₂ can be supplied at 0-4 SCCM, preferably at 0-1.5 SCCM. If H₂ is used, the H2 is supplied via inlet 116 with a flow rate of approximately 1-5 SCCM, preferably 2-3 SCCM, while O₂ can be supplied at 2-10 SCCM, preferably at 4.5-6.5 SCCM, with Ar supplied at 80-150 SCCM, preferably at 120 SCCM. The chamber temperature is maintained below 250° C., preferably between 25° C. and 100° C.

Note that in embodiments of the present invention either water vapor or hydrogen gas can be used to assist the sputtering process. In some cases, hydrogen might be preferred because it is easier to remove hydrogen gas in a system where multiple vacuum deposition chambers are coupled together for automated sequential growth (e.g., by pumping down at the entrance of the sputtering chamber), whereas water vapor is more difficult to remove due to possible condensation, since vacuum pumps are not very effective in removing water in liquid form.

As free electrons in sputtering chamber 100 are accelerated between cathode 102 and anode 110, these accelerated electrons approach the outer shell electrons of neutral gas atoms and molecules (Ar, O₂, and H₂/H₂O), and drive these electrons off the gas atoms. This collision leaves the gas atoms ionized. Particularly, the heavy, positively charged Ai′ ions are accelerated toward negatively charged cathode 102, striking the surface and blasting atoms off target material 104. The target atoms then travel through the chamber and are deposited on the surface of wafer 108. Magnetic field 106 helps confine the electrons close to target 104 and away from wafer 108, hence preventing wafer 108 from being damaged by the accelerated electrons.

In conventional sputtering techniques that do not apply water vapor or hydrogen, the chamber temperature is usually maintained at between 300° C. and 500° C., which is more likely to damage the solar cell junction structure. In addition, with the conventional sputtering technique without the use of water vapor or hydrogen, the deposition of TCO material (typically Indium Tin Oxide, ITO) results in formation of a TCO film with a poly-crystalline structures and relatively large crystal grain sizes. In contrast, in the new sputtering technique described here, the presence of water vapor or hydrogen introduces hydrogen (H+) and hydroxyl (OH—) ions into the deposition environment. These ions are likely to attach to the In atoms and cause them to be less mobile. As a result, the TCO film formed by the new sputtering technique with the use of water vapor or hydrogen is more likely to be in an amorphous state. The sputtering process continues until the desired TCO film thickness is reached.

Subsequent to the sputtering process, wafer 108 with the newly formed TCO film is annealed. The annealing process can occur in air, vacuum or in an environment filled with N₂ and H₂. The annealing temperature can be 100-300° C., preferably at approximately 150-200° C., for approximately 15 to 60 minutes. The annealing process subjects the TCO film to a re-crystallization process, which results in a poly-crystalline structure with relatively larger grain sizes. The larger crystal grain size results in a higher carrier mobility. In one embodiment, after annealing, the TCO film exhibits an average carrier density less than 3×10²⁰/cm³, a carrier mobility greater than 70 cm²/(V·s). As a result, the resistivity of the TCO film, which is the reciprocal of the product of carrier density and carrier mobility, is less than 500 μΩ·cm, preferably less than 400 μΩ·cm.

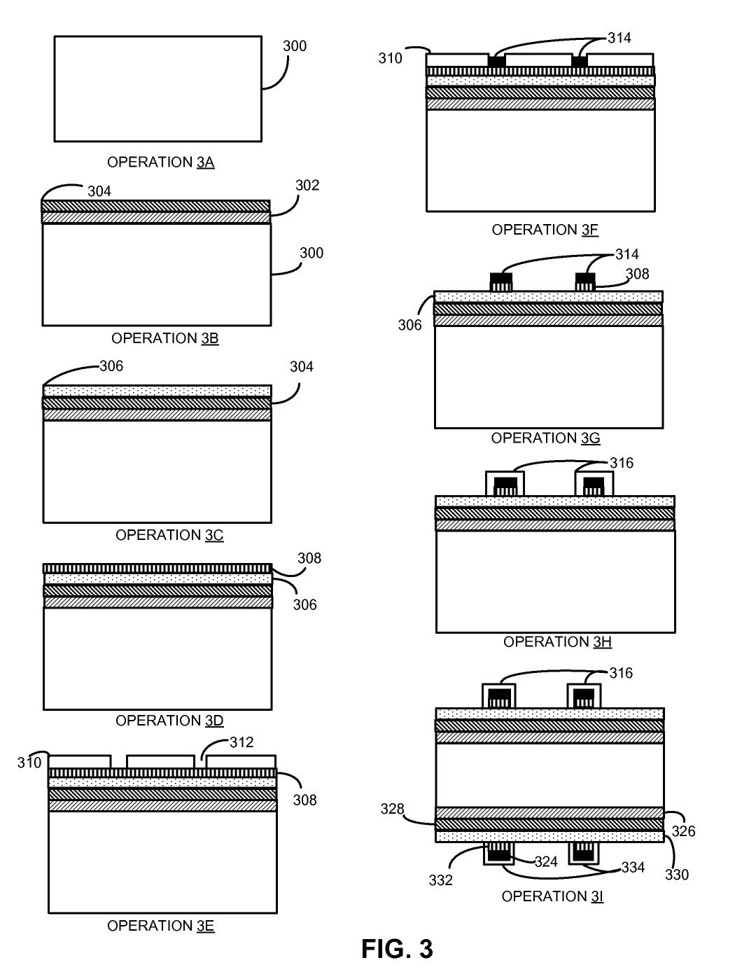

FIG. 1B presents a flow chart illustrating an exemplary process of fabricating a solar cell with a low-resistivity TCO layer, in accordance with one embodiment of the present invention. During operation, a multi-layer solar cell structure is obtained on a wafer (operation 142, a detailed fabrication process is described in conjunction with FIG. 3). The wafer is then placed in a sputtering chamber and subject to a sputtering process (operation 144). The sputtering process, as previously described in conjunction with FIGS. 1A and 1B, uses water vapor or hydrogen gas and the sputtering occurs at a temperature between 25 and 100° C. In one embodiment, the sputtering target material includes In₂O₃/TiO₂ alloy, In₂O₃/WO₂ alloy, or In₂O₃. In further embodiments, the target material includes In₂O₃ and SnO₂. Other target materials can also be used.

Subsequent to the sputtering process, the resulting TCO film together with the wafer and solar cell structure is subject to an annealing process (operation 146). The annealing can occur in air, vacuum, or a N₂+H₂ environment, at approximately 150-200° C., for approximately 15-60 minutes.

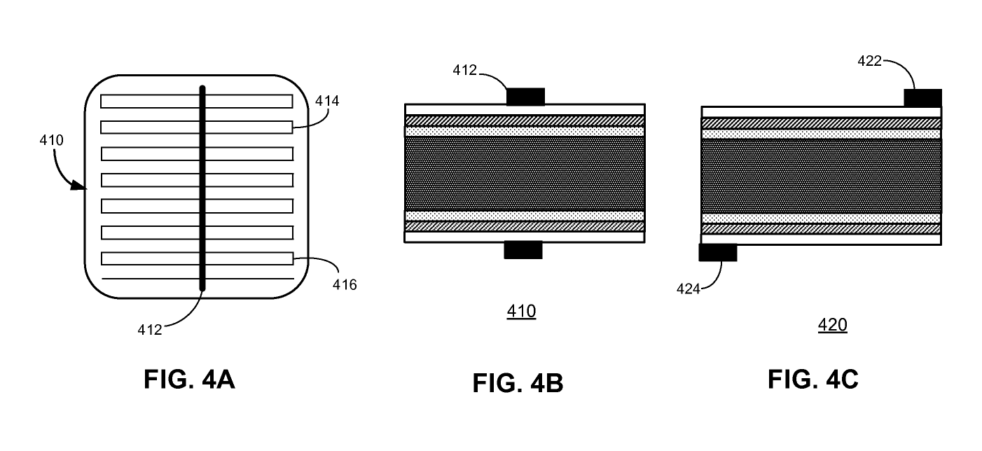

After the TCO layer is annealed, the wafer (with the TCO layer exposed) is patterned and a seed metal layer is deposited on areas on the TCO layer that are supposed to be covered by an electrode material (operation 148). Subsequently, a copper grid is electroplated onto the metal seed layer (operation 150). The process of depositing the seed layer and electroplating the metal grid electrode is described in more detail in conjunction with FIG. 4. After the electrode layer is completed, the solar cell is assembled with other solar cells into a solar panel (operation 152).

### Solar Cell Fabrication

In some embodiments of the present invention, the semiconductor structure below the TCO layer is a crystalline-Si (c-Si)-based solar cell having its heterojunction at the backside (away from the direct incident light). The back junction solar cell further includes a thin dielectric layer functioning as an interface passivation layer as well as a quantum-tunneling barrier (QTB). The solar cell can be fabricated by depositing a high-quality ultra-thin oxide layer, which provides passivation and enables quantum tunneling of carriers, on the front and back surfaces of a c-Si substrate. Subsequently, a hydrogenated graded-doping amorphous-Si (a-Si) layer having an opposite conductive doping type of that of the c-Si substrate is deposited on the back oxide layer to form the solar cell emitter. Another layer of hydrogenated a-Si having the same conductive doping type of that of the c-Si substrate is deposited on the front oxide layer to form a front surface-field layer that passivates the front surface.

The conventional heterojunction solar cells often have the so-called front-junction structure, meaning the p-n junction of the solar cells are located at the front side, the side that faces the sunlight, of the solar cells. There are several inherent deficiencies associated with such a front-junction structure that limits the solar cell performance. First, because the solar cell substrates are often n-type doped, the emitter layers need to be p-type doped. The p-type doped emitter layer (or the boron-doped Si layer) often has a high defect density, resulting in a higher recombination rate of generated excess carriers, which translates to a reduced solar cell current. To mitigate such a carrier loss, in practice, these solar cells often have a relatively thin emitter layer or an emitter layer with a low dopant activation rate. For example, the thickness of the emitter layer of a typical front-junction solar cell is between 4 and 6 nm. This can result in the emitter layer being partially depleted because the emitter layer is sandwiched between a TCO layer (normally n-type doped) and an intrinsic a-Si or dielectric layer. This partially depleted, p-type doped emitter layer makes it harder to achieve optimal work function matching between the emitter and the front TCO layer. A TCO layer with high work function may be needed.

Moreover, because the emitter is on the light-facing side of the solar cell, the region near the light-facing surface tends to have a higher carrier density, which can result in increased junction recombination of the generated excess carriers. In addition, the p-type doped emitter can have a degradation that is similar to the light-induced degradation (LID) because more active boron dopants are facing the sunlight.

To overcome these deficiencies, embodiments of the present invention are based on an ultra-high performance solar cell that has a back-junction structure and an oxide tunneling layer. The back junction solar cell has its emitter located at the side that faces away from the incoming sunlight, thus minimizing the loss of current due to short wavelength absorption, which occurs near the front surface of the solar cell. In addition, while located at the backside, facing away from the direct sunlight, the p-typed doped emitter can be thicker to eliminate the emitter depletion effect without compromising the short-wavelength-absorption-induced current loss. As a result, V_{oc} and fill factor can be improved. The back junction also provides more flexibility for tuning the p-type doped emitter work function, thus allowing a better work function matching between the emitter layer and the corresponding TCO layer. Hence, it is possible to select a more optimal back TCO material without being limited by its transmission properties. The back location of the junction also means that the solar cell is less affected by the higher-energy excess carrier recombination at the junction because the back junction is mostly impacted by longer-wavelength, lower-energy absorption.

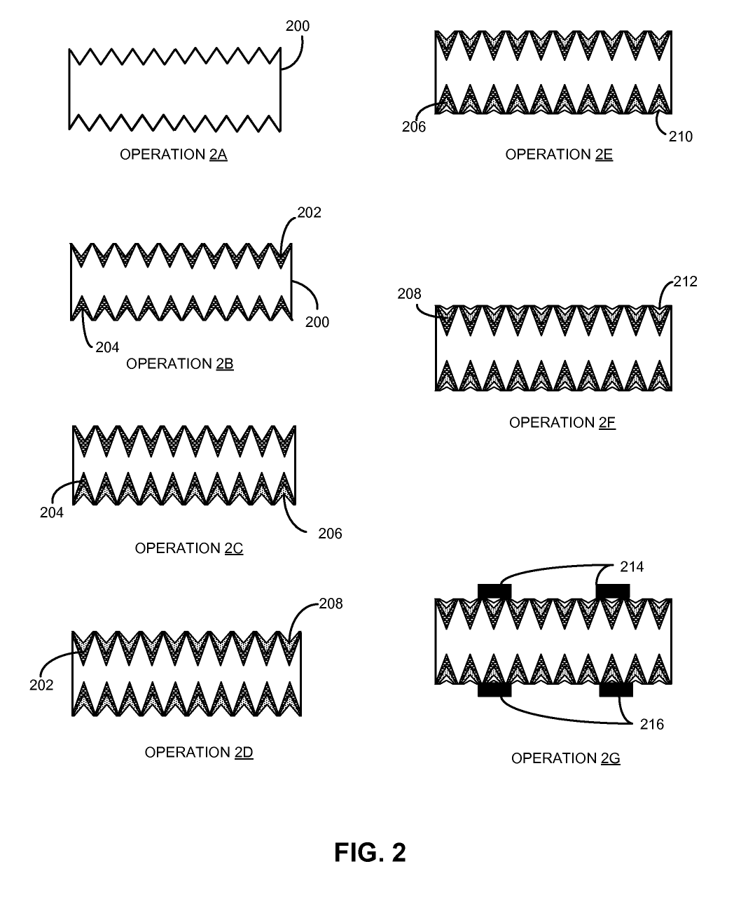

Either n- or p-type doped high-quality solar-grade silicon (SG-Si) wafers can be used to build the back junction solar cell. In one embodiment, an n-type doped SG-Si wafer is selected. FIG. 2 presents a diagram illustrating the process of fabricating a back junction solar cell with tunneling oxide, in accordance with an embodiment of the present invention.

In operation 2A, an SG-Si substrate 200 is prepared. The thickness of SG-Si substrate 200 can range between 80 and 200 μm. In one embodiment, the thickness of SG-Si substrate 200 rages between 90 and 120 μm. The resistivity of SG-Si substrate 200 is typically in, but not limited to, the range between 1 Ω·cm and 10 Ω·cm. In one embodiment, SG-Si substrate 200 has a resistivity between 1 Ω·cm and 2 Ω·cm. The preparation operation includes typical saw damage etching that removes approximately 10 μm of silicon and surface texturing. The surface texture can have various patterns, including but not limited to: hexagonal-pyramid, inverted pyramid, cylinder, cone, ring, and other irregular shapes. In one embodiment, the surface texturing operation results in a random pyramid textured surface. Afterwards, SG-Si 200 substrate goes through extensive surface cleaning. Note that in FIG. 2 the texture pattern is not drawn to the actual scale and is enlarged to illustrate the texture. Actual texture pattern would be much smaller compared with the surface dimensions.

In operation 2B, a thin layer of high-quality (with Dᵢₜ less than 1×10¹¹/cm²) dielectric material is deposited on the front and back surfaces of SG-Si substrate 200 to form front and back passivation/tunneling layers 202 and 204, respectively. In one embodiment, only the back surface of SG-Si substrate 200 is deposited with a thin layer of dielectric material. Various types of dielectric materials can be used to form the passivation/tunneling layers, including, but not limited to: silicon oxide (SiOₓ), hydrogenerated SiOₓ, silicon nitride (SiNₓ), hydrogenerated SiNₓ, aluminum oxide (AlOₓ), silicon oxynitride (SiON), and hydrogenerated SiON. In addition, various deposition techniques can be used to deposit the passivation/tunneling layers, including, but not limited to: thermal oxidation, atomic layer deposition, wet or steam oxidation, low-pressure radical oxidation, plasma-enhanced chemical-vapor deposition (PECVD), etc. The thickness of tunneling/passivation layers 202 and 204 can be between 1 and 50 angstroms. In one embodiment, the thickness of tunneling/passivation layers 202 and 204 is between 1 and 15 angstroms. Note that the well-controlled thickness of the tunneling/passivation layers ensures good tunneling and passivation effects.

In operation 2C, a layer of hydrogenerated, graded-doping a-Si having a doping type opposite to that of substrate 200 is deposited on the surface of back passivation/tunneling layer 204 to form emitter layer 206. As a result, emitter layer 206 is situated on the backside of the solar cell facing away from the incident sunlight. Note that, if SG-Si substrate 200 is n-type doped, then emitter layer 206 is p-type doped, and vice versa. In one embodiment, emitter layer 206 is p-type doped using boron as dopant. SG-Si substrate 200, back passivation/tunneling layer 204, and emitter layer 206 form the hetero-tunneling back junction. The thickness of emitter layer 206 is between 1 and 20 nm. Note that an optimally doped (with doping concentration varying between 1×10¹⁵/cm³ and 5×10²⁰/cm³) and sufficiently thick (at least between 3 nm and 20 nm) emitter layer is necessary to ensure a good ohmic contact and a large built-in potential. In one embodiment, the region within emitter layer 206 that is adjacent to front passivation/tunneling layer 202 has a lower doping concentration, and the region that is away from front passivation/tunneling layer 202 has a higher doping concentration. The lower doping concentration ensures minimum defect density at the interface between back passivation/tunneling layer 204 and emitter layer 206, and the higher concentration on the other side prevents emitter layer depletion. The work function of emitter layer 206 can be tuned to better match that of a subsequently deposited back transparent conductive oxide (TCO) layer to enable larger V_{oc} and a higher fill factor. In addition to a-Si, it is also possible to use other material, including but not limited to: one or more wide-bandgap semiconductor materials and polycrystalline Si, to form emitter layer 206.

In operation 2D, a layer of hydro generated, graded-doping a-Si having a doping type same as that of substrate 200 is deposited on the surface of front passivation/tunneling layers 202 to form front surface field (FSF) layer 208. Note that, if SG-Si substrate 200 is n-type doped, then FSF layer 208 is also n-type doped, and vise versa. In one embodiment, FSF layer 208 is n-type doped using phosphorous as dopant. SG-Si substrate 200, front passivation/tunneling layer 202, and FSF layer 208 form the front surface high-low homogenous junction that effectively passivates the front surface. In one embodiment, the thickness of FSF layer 208 is between 1 and 30 nm. In one embodiment, the doping concentration of FSF layer 208 varies from 1×10¹⁵/cm³ to 5×10²⁰/cm³. In addition to a-Si, it is also possible to use other material, including but not limited to: wide-bandgap semiconductor materials and polycrystalline Si, to form FSF layer 208.

In operation 2E, a layer of TCO material is deposited, using the sputtering method described in conjunction with FIGS. 1A and 1B, on the surface of emitter layer 206 to form a back-side conductive anti-reflection layer 210, which ensures a good ohmic contact. Examples of TCO include, but are not limited to: indium-titanium-oxide (ITiO), indium oxide (In₂O₃), indium-tungsten-oxide (IWO), indium-tin-oxide (ITO), indium-zinc-oxide (IZO), tin-oxide (SnOₓ), aluminum doped zinc-oxide (ZnO:Al or AZO), Zn—In—O (ZIO), gallium doped zinc-oxide (ZnO:Ga), and other large bandgap transparent conducting oxide materials. The work function of back-side TCO layer 210 can be tuned to better match that of emitter layer 206.

In operation 2F, front-side TCO layer 212, which can have a similar material composition as back-side TCO layer 210, is formed on the surface of FSF layer 208. Front-side TCO layer 212 forms a good anti-reflection coating to allow maximum transmission of sunlight into the solar cell. Note that operation 2E and 2F can occur with the same sputtering process as described in conjunction with FIGS. 1A and 1B, or can occur with two separate sputtering processes, using the same or different TCO materials.

In operation 2G, front-side electrode 214 and back-side electrode 216 are formed on the surfaces of TCO layers 212 and 210, respectively. In one embodiment, front-side electrode 214 and back-side electrode 216 include metal finger grids, wherein the metal can include Cu, Ag, Al, Au, or any conductive material. The conductive grid can be formed using various techniques, including, but not limited to: electroplating, screen printing of a metal paste, inkjet or aerosol printing of a conductive ink, and evaporation. In one embodiment, front-side electrode 214 and/or back-side electrode 216 can include Cu grid formed using various techniques, including, but not limited to: electroless plating, electro plating, sputtering, and evaporation.

Although the example illustrated in FIG. 2 is based on a back-heterojunction device structure, embodiments of the present invention can be applied to various, different device structures, such as solar cells whose emitter is on the front side, or solar cells whose electrodes of both polarity are on the back side (i.e., with an interdigitated backside contacts, IBC). Furthermore, the methods for fabricating a low-resistivity TCO layer can be used in various applications and devices other than solar cell. Such applications include touch screens and flexible display devices.

FIG. 3 presents a diagram illustrating an exemplary process of fabricating a solar cell with a low-resistivity TCO layer and electrodes, in accordance with an embodiment of the present invention.

In operation 3A, a Si substrate 300 is prepared. The process used for preparing Si substrate 300 is similar to the one used in operation 2A.

In operation 3B, an oxide layer 302 is grown on Si substrate 300 to form a passivation layer, and an a-Si layer 304 with graded doping is deposited on oxide layer 302 to form an emitter. The deposition technique used for depositing layers 304 and 302 is similar to the one used in operations 2B, 2C, and 2D.

In operation 3C, a layer of low-resistivity TCO material is deposited on top of a-Si layer 304 to form an anti-reflection layer 306. The formation process of TCO layer 306 is described in conjunction with FIGS. 1A and 1B, and is similar to the one used in operations 2E and 2F.

In operation 3D, a thin metal layer 308 is deposited on top of TCO layer 306. Thin metal layer 308 can be deposited using a physical vapor deposition (PVD) technique, such as sputtering deposition or evaporation, with the assistance of water vapor or hydrogen gas. Thin metal layer 308 can include Cu, Ni, Ag, NiV, Ti, Ta, W, TiN, TaN, WN, TiW, NiCr, and their combinations. Thin metal layer 308 can also be a metal stack that includes a layer of one or more of the aforementioned metals directly deposited on TCO layer 306 and a layer of subsequently deposited copper, or a layer of copper only. The thickness of the copper seed layer can be between 20 nm and 500 nm. Forming thin metal layer 308 on top of TCO layer 306 improves the adhesion between TCO layer 306 and the subsequently deposited front-side metal grid.

In operation 3E, a patterned masking layer 310 is deposited on top of thin-metal layer 308. The openings of masking layer 310, such as opening 312, correspond to the locations of a designed front-side metal grid. Masking layer 308 can include a patterned photo resist layer, which can be formed using a photolithography technique. In one embodiment, the photo resist layer is formed by screen-printing resist on top of the wafer. The photo resist is then baked to remove solvent. A mask is laid on the photo resist, and the wafer is exposed to UV light. After the UV exposure, the mask is removed, and the photo resist is developed in a photo resist developer. Opening 312 is formed after develop. The photo resist can also be applied by spraying, dip coating, or curtain coating. Dry film resist can also be used. Alternatively, masking layer 308 can include a layer of patterned silicon oxide (SiO₂). In one embodiment, masking layer 308 is formed by first depositing a layer of SiO₂ using a low-temperature plasma-enhanced chemical-vapor-deposition (PECVD) technique. In a further embodiment, masking layer 208 is formed by dip-coating the front surface of the wafer using silica slurry, followed by screen-printing an etchant that includes hydrofluoric acid or fluorides. Other masking materials are also possible, as long as the masking material is electrically insulating.

In operation 3F, one or more layers of metals are deposited at the openings of masking layer 310 to form a metal grid 314. In one embodiment, an electroplating process is used to deposit a metal grid 314. Metal grid 314 can be formed using an electroplating technique, which can include electrodeposition and/or electroless deposition. In one embodiment, TCO layer 206 is coupled to the cathode of the plating power supply, which can be a direct current (DC) power supply, via an electrode. TCO layer 306 and masking layer 310, which includes the openings, are submerged in an electrolyte solution which permits the flow of electricity. Note that, because only the openings within masking layer 310 are electrically conductive, metals will be selectively deposited into the openings, thus forming a metal grid with a designed pattern. Metal grid 314 can be a single layer structure, such as a single layer of Cu or Ag; or a multilayer structure, such as a Ni/Cu bi-layer structure, a Cu/Sn bi-layer structure, a Ni/Cu/Sn tri-layer structure, and a Ni/Cu/Ag tri-layer structure. The sidewalls and top of metal grid 314 can also be coated with Ag or Sn, which protects the electrode grid from peeling. When a layer of Cu is deposited, a Cu plate or a basket of copper chunks is used at the anode, and the solar cell is submerged in the electrolyte suitable for Cu plating. The current used for Cu plating is between 0.1 A and 2 A for a wafer with a dimension of 125 mm×125 mm, and the thickness of the Cu layer is approximately tens of micrometers. Other parameters may be used for wafers with different dimensions. The deposition of a Ni layer can also be an electroplating process, during which a Ni plate is used at the anode, and the solar cell is submerged in the electrolyte suitable for Ni plating. The voltage used for Ni plating can be between 1 V and 3 V. In cases where the back side of the wafer is also covered with a layer of TCO, the cathode of the plating power supply can be coupled to the TCO layer on the back side of the wafer, and the whole wafer is submerged in the electrolyte solution. The cathode can also be directly in contact with the front side by using contact pins at the openings of masking layer 310. Metal stacks deposited using the electroplating technique often have lower resistivity compared with low-temperature-cured silver paste layers. In one embodiment, the resistivity of metal grid 314 is less than 2×10⁻⁵ Ω·cm. In contrast, Ag paste cured at 200° C. often has a resistivity greater than 2×10⁻⁵ Ω·cm. The lower resistivity of the metal grid can significantly enhance solar cell efficiency.

In operation 3G, masking layer 310 and portions of thin metal layer 308 are removed to expose the portions of TCO layer 306 not covered by metal grid 314. As a result, metal grid 314 is completed with the designed pattern and line width. If thin metal layer 308 is transparent, then operation 3G can only remove masking layer 310. In one embodiment, thin metal layer 308 includes an ultrathin NiCr layer, which is transparent and remains intact after operation 3G.

In operation 3H, a protective metal layer 316 is deposited on metal grid 314, covering the top and sidewalls of metal grid 314 and optionally the sidewalls of thin metal layer 308. In one embodiment, protective metal layer 316 includes, but is not limited to: Sn and Ag. Note that by covering the entire surface of metal grid 314, including the sidewalls, protective metal layer 316 prevents metal grid 314 from oxidation. In addition, protective metal layer 316 provides solderbility to the busbars, making it possible for subsequent tabbing process. Because TCO layer 306 is electrically conductive, the electroplating process is no longer an option for depositing protective metal layer 316. In one embodiment, protective layer 316 is deposited using a metal immersion process. During fabrication, the solar cell is immersed in a solution that includes metal ions, such as Sn and Ag ions. A displacement reaction occurs between the metal ions in the solution and the surface metal of metal grid 314. For Cu-based metal grid 314, the Sn or Ag ions in the solution displaced Cu ions on the top and sidewalls of metal grid 314. As a result, a layer of Sn or Ag covers the top and sidewalls of metal grid 314 completely.

Note that in order for the displacement reaction to occur, the metal ions in the solution need to have a higher redox potential than that of the metal to be displaced. This is different from electroplating and the electroless plating processes. The electroplating process takes place under current, and the electroless plating process requires a reducing agent to reduce the metal ions in the solution to the plated metal.

Because the redox potential of Cu is greater than that of Sn, deposition of Sn on the surface of a Cu grid by immersion cannot be driven by potential differences as a normal displacement reaction. Instead, a complexing agent, such as Thiourea (SC(NH₂)₂) and its derivants (or derivatives), can be used to alter the reverse potential for the displacement reaction, thus allowing the reaction to take place. More specifically, Thiourea reduces the redox potential of Cu from +0.34 V to −0.39 V, comparing with the redox potential of Sn at −0.14 V. The Cu ions can then replace the Sn ions from the salt solution. The displacement reaction can be expressed as:

2Cu+Sn⁺⁺+4SC(NH₂)₂→2Cu⁺+4SC(NH₂)₂+Sn.

In one embodiment, the chemical solution used for immersion plating of Sn includes, but not limited to: Sn salt for providing Sn ions, Thiourea or its derivants used as a complexing agent, acid (such as H₂SO₄) for keeping an acidic environment to prevent deposition of Sn on TCO layer 306, accelerator, stabilizer, and surfactant. In addition to immersion plating of Sn, immersion plating of Ag can also be performed, either by applying a separate immersion plating to form an additional layer of coating, or by mixing Sn and Ag ions in the chemical solution to achieve simultaneous Sn and Ag coating.

In operation 3I, back-side oxide layer 326, back-side a-Si layer 328, back-side TCO layer 330, thin metal layer 332, back-side metal grid 324, and back-side protective metal layer 334 are formed on the back side of the wafer using a process that is similar to the one used in operations 3B through 3G.

In some embodiments of the present invention, the front and back metal grids, such as the finger lines, can include electroplated Cu lines. By using an electroplating or electroless plating technique, one can obtain Cu grid lines with a resistivity of equal to or less than 5×10⁻⁶ Ω·cm. In addition, a metal seed layer (such as Ti) can be deposited directly on the TCO layer using, for example, a physical vapor deposition (PVD) process. This seed layer ensures excellent ohmic contact with the TCO layer as well as a strong physical bond with the solar cell structure. Subsequently, the Cu grid can be electroplated onto the seed layer. This two-layer (seed layer and electroplated Cu layer) ensures excellent ohmic contact quality, physical strength, low cost, and facilitates large-scale manufacturing. Details about an electroplated Cu grid (and optionally a metal seed layer deposited directly on the TCO layer) can be found in U.S. patent application Ser. No. 12/835,670 (Attorney Docket No. SSP10-1001US), entitled “Solar Cell with Metal Grid Fabricated by Electroplating,” by inventors Jianming Fu, Zheng Xu, Chentao Yu, and Jiunn Benjamin Heng, filed 13 Jul. 2010; U.S. patent application Ser. No. 13/679,913 (Attorney Docket No. SSP10-1001CIP), entitled “SOLAR CELL WITH METAL GRID FABRICATED BY ELECTROPLATING,” by inventors Bob Wen Kong and Jianming Fu, filed 16 Nov. 2012; and U.S. patent application Ser. No. 13/220,532 (Attorney Docket No. SSP10-1010US), entitled “Solar Cell with Electroplated Metal Grid,” by inventors Jianming Fu, Jiunn Benjamin Heng, Zheng Xu, and Chentao Yu, filed 29 Aug. 2011, the disclosures of which are incorporated by reference in their entirety herein.

The reduced resistance of the Cu grid lines (also referred to as “fingers”) makes it possible to reduce the number of busbars on the solar cell surface. In some embodiments of the present invention, a single busbar is used to collect the current from the fingers.

FIG. 4A illustrates the surface of an exemplary bifacial solar cell with a single center busbar, in accordance with an embodiment of the present invention. In FIG. 4, the front or back surface of a solar cell 410 includes a single busbar 412 and a number of finger lines, such as finger lines 414 and 416. FIG. 4B illustrates a cross-sectional view of the bifacial solar cell with a single center busbar per surface, in accordance with an embodiment of the present invention. The semiconductor multilayer structure shown in FIG. 4B can be similar to the one shown in FIG. 2. Note that the finger lines are not shown in FIG. 4B because the cut plane is between two finger lines. In the example shown in FIG. 4B, a busbar 412 runs in the direction that is perpendicular to the paper, and the finger lines run from left to right. Because there is only one busbar on each surface, the distances from the edges of the fingers to the busbar are longer. However, the elimination of one busbar reduces shading, which not only compensates for the power loss caused by the increased finger-to-busbar distance, but also provides additional power gain.

Note that in some embodiments of the present invention, the solar cell can operate in a bifacial mode. In other words, because the low-resistivity TCO layer is used on both surfaces of the solar cell, and the backside of the solar cell remains transparent, the solar cell can receive light from both the front and back surfaces. Such configuration allows the solar cell to achieve a substantially higher efficiency in applications such as solar farm.

FIG. 4C illustrates a cross-sectional view of bifacial solar cell 420. The semiconductor multilayer structure shown in FIG. 4C can be similar to the one shown in FIG. 2. Like FIG. 4B, in FIG. 4C, the finger lines (not shown) run from left to right, and the busbars run in the direction that is perpendicular the paper. The busbars on the front and the back surfaces of bifacial solar cell 420 are placed adjacent to opposite edges of the cell. This configuration can further improve power gain because the busbar-induced shading now occurs at locations that were less effective in energy production.

The single busbar configurations (either the center busbar or the edge busbar) not only can provide power gain, but also can reduce fabrication cost, because less metal will be needed. Moreover, the metal finger lines can have a cross-section with a curved profile to deflect incident light that otherwise would be blocked onto the cell surface, thus further reducing the shading effect. For bifacial operation, both the front and back covers of a solar panel can be transparent. These covers can be made from glass or polymer. Such bifacial panels can absorb light from both the “front” (facing sunlight) and “back” (facing away from the sunlight) surfaces, which allows the cell to convert both direct and indirect sunlight. Indirect sunlight can include reflected, deflected, and diffused sunlight from various surfaces surrounding the panel. Such bifacial solar panels are particularly useful in settings where the panels are elevated from a flat surface, such as in a solar farm environment.

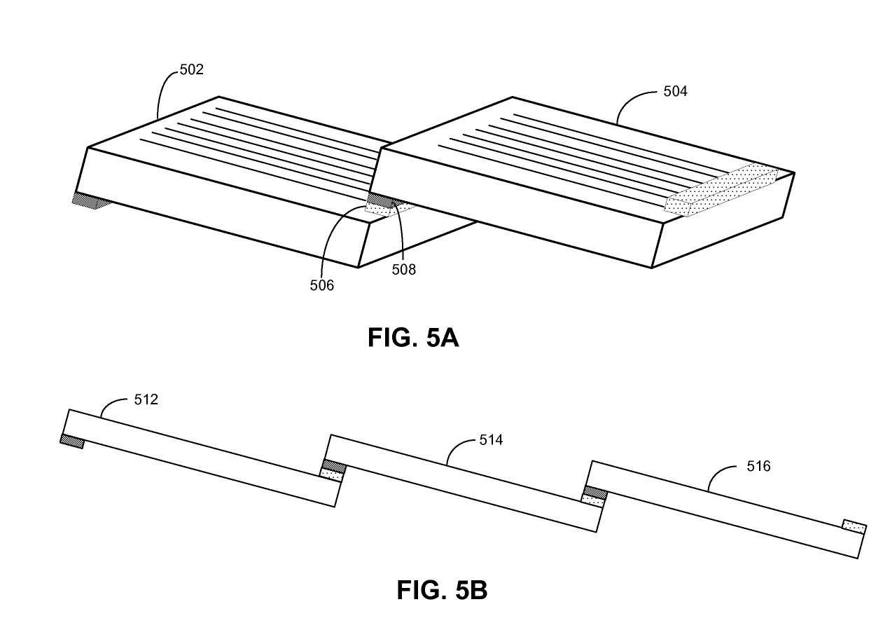

In addition to using a single tab to connect adjacent smaller cells in series, in some embodiments, the serial connection between adjacent smaller cells is achieved by partially overlapping the adjacent smaller cells, thus resulting in the direct contact of the corresponding edge busbars. FIG. 5A presents a diagram illustrating the serial connection between two adjacent cells with low-resistivity TCO layers using a single edge busbar per surface, in accordance with an embodiment of the present invention. In FIG. 5A, cell 502 and cell 504 are coupled to each other via an edge busbar 506 located at the top surface of smaller cell 502 and an edge busbar 508 located on the bottom surface of cell 504. More specifically, the bottom surface of smaller cell 1304 partially overlaps with the top surface of smaller cell 502 at the edge in such a way that bottom edge busbar 508 is placed on top of and in direct contact with top edge busbar 506.

In some embodiments, the edge busbars that are in contact with each other are soldered together to enable the serial electrical connection between adjacent smaller cells. In further embodiments, the soldering may happen concurrently with a lamination process, during which the edge-overlapped smaller cells are placed in between a front-side cover and a back-side cover along with appropriate sealant material, which can include adhesive polymer, such as ethylene vinyl acetate (EVA). During lamination, heat and pressure are applied to cure the sealant, sealing the solar cells between the front-side and back-side covers. The same heat and pressure can result in the edge busbars that are in contact, such as edge busbars 506 and 508, being soldered together. Note that if the edge busbars include a top Sn layer, there is no need to insert additional soldering or adhesive materials between the top and bottom edge busbars (such as edge busbars 506 and 508) of adjacent solar cells. Also note that because the smaller cells are relatively flexible, the pressure used during the lamination process can be relatively large without the worry that the cells may crack under such pressure. In some embodiments, the pressure applied during the lamination process can be above 1.0 atmospheres, such as 1.2 atmospheres.

FIG. 5B presents a diagram illustrating the side-view of a string of adjacent edge-overlapped cells with low-resistivity TCO layers, in accordance with an embodiment of the present invention. In FIG. 5B, cell 512 partially overlaps with adjacent cell 514, which also partially overlaps (on its opposite end) with cell 516. Such a string of smaller cells forms a pattern that is similar to roof shingles. Ideally, the overlapping is kept to a minimum to minimize shading caused by the overlapping. In some embodiments, the single busbars (both at the top and the bottom surface) are placed at the very edge of the cell (as shown in FIG. 5B), thus minimizing the overlapping. The same shingle pattern can extend along all cells in a row. Detailed descriptions of serially connecting solar cells in a shingled pattern can be found in U.S. patent application Ser. No. 14/510,008 (Attorney Docket No. SSP13-1001CIP), entitled “MODULE FABRICATION OF SOLAR CELLS WITH LOW RESISTIVITY ELECTRODES,” by inventors Jiunn Benjamin Heng, Jianming Fu, Zheng Xu, and Bobby Yang and filed 8 Oct. 2014, the disclosure of which is incorporated by reference in its entirety herein.

Note that although the examples above illustrate adjacent solar cells being physically coupled with direct contact in a “shingling” configuration, in some embodiments of the present invention the adjacent solar cells can also be coupled electrically in series using conductive materials without being in direct contact with one another.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

1-8. (canceled)

9. A method for fabricating a solar cell, comprising:
placing a photovoltaic structure in a vacuum chamber wherein the photovoltaic structure includes a first doped amorphous-Si layer on a first side;
depositing a transparent conductive oxide layer directly onto the first doped amorphous-Si layer in a deposition environment that contains water vapor or hydrogen gas using a physical vapor deposition technique, wherein the deposition environment is maintained at a temperature lower than 250° C., and wherein the transparent conductive oxide layer comprises indium oxide, indium-titanium-oxide, or indium-tungsten-oxide; and
annealing the transparent conductive oxide layer subsequent to the deposition.

10. (canceled)

11. The method of claim 9, wherein the deposition environment is maintained at a temperature between 25° C. and 100° C.

12. The method of claim 9, wherein the water vapor in the deposition environment has a pressure between 1×10⁻⁷ and 1×10⁻⁴ Torr.

13. The method of claim 12, wherein the water vapor pressure is approximately 3-10×10⁻⁶ Torr.

14. The method of claim 9, wherein the annealing is performed for 15 to 60 minutes.

15. The method of claim 9, wherein the annealing is performed at approximately 150-200° C.

16. The method of claim 9, wherein the annealing is performed in air, vacuum, or an environment that contains N₂ and H₂.

17. The method of claim 9, wherein the physical vapor deposition technique comprises a sputtering process;
wherein the sputtering process comprises bombarding a target material in presence of water vapor or hydrogen; and
wherein the target material comprises: indium oxide, indium-titanium-oxide, or indium-tungsten-oxide.

18-21. (canceled)

22. A fabrication system, comprising:
a vacuum chamber configured to hold a photovoltaic structure, wherein the photovoltaic structure includes a first doped amorphous-Si layer on a first side; and
a deposition mechanism configured to deposit a transparent conductive oxide layer directly onto the first doped amorphous-Si layer, wherein the transparent conductive oxide layer comprises indium oxide, indium-titanium-oxide, or indium-tungsten-oxide, wherein during deposition the vacuum chamber is filled with water vapor or hydrogen gas, and wherein during deposition the photovoltaic structure is maintained at a temperature lower than 250° C.; and
an annealing mechanism configured to anneal the transparent conductive oxide layer subsequent to the deposition.

23. The fabrication system of claim 22, wherein during deposition the photovoltaic structure is maintained at a temperature between 25° C. and 100° C.

24. The fabrication system of claim 22, wherein the water vapor in the vacuum chamber has a pressure between 1×10⁻⁷ and 1×10⁻⁴ Torr.

25. The fabrication system of claim 24, wherein the water vapor in the vacuum chamber has a pressure between 3×10⁻⁶ and 10×10⁻⁶ Torr.

26. The fabrication system of claim 22, wherein the annealing mechanism is configured to perform the annealing process for 15 to 60 minutes.

27. The fabrication system of claim 22, wherein the annealing mechanism is configured to perform the annealing process at a temperature between 150 and 200° C.

28. The fabrication system of claim 22, wherein the annealing mechanism is configured to perform the annealing in air, vacuum, or an environment that contains N₂ and H₂.

29. The fabrication system of claim 22, wherein the deposition mechanism comprises a sputtering machine, wherein the sputtering machine comprises a target made of a material comprising indium oxide, indium-titanium-oxide, or indium-tungsten-oxide; wherein while depositing the transparent conductive oxide layer, the target is bombarded in presence of water vapor or hydrogen.
